(19) United States
(12) Patent Application Publication
(10) Pub. No.: US 2010/0200974 A1
(43) Pub. Date: Aug. 12, 2010

(54) SEMICONDUCTOR PACKAGE STRUCTURE USING THE SAME

(76) Inventors: Chao-Fu Weng, Tainan City (TW); Tsung-Yueh Tsai, Kaohsiung (TW); Chang-Ying Hung, Kaohsiung City (TW); Jen-Chieh Kao, Kaohsiung City (TW)

Correspondence Address: Muncy, Geissler, Olds & Lowe, PLLC, 4000 Legato Road, Suite 310, FAIRFAX, VA, 22033, US

(21) Appl. No.: 12/505,071

(22) Filed: Jul. 17, 2009

(30) Foreign Application Priority Data
Feb. 11, 2009 (TW) 98104391

(51) Int. Cl. H01L 23/52; H01L 23/49; H01L 23/28

(52) U.S. Cl. 257/686; 257/692; 257/E23.116; 257/E23.141; 257/E23.024

(57) ABSTRACT

A semiconductor package structure using the same is provided. The semiconductor package structure includes a first semiconductor element, a second semiconductor element, a binding wire and a molding compound. The first semiconductor element includes a semiconductor die and a pad. The pad is disposed above the semiconductor die and includes a metal base, a hard metal layer disposed above the metal base and an anti-oxidant metal layer disposed above the hard metal layer. The hardness of the hard metal layer is larger than that of the metal base. The activity of the anti-oxidant metal layer is lower than that of the hard metal layer. The first semiconductor element is disposed above the second semiconductor element. The bonding wire is connected to the pad and the second semiconductor element. The molding compound seals the first semiconductor element and the bonding wire and covers the second semiconductor element.

This application claims the benefit of Taiwan application Serial No. 98104391, filed Feb. 11, 2009, the subject matter of which is incorporated herein by reference.

### BACKGROUND OF THE INVENTION

1. Field of the Invention

The invention relates in general to a semiconductor package structure, and more particularly to a package structure soldered with a bonding wire.

2. Description of the Related Art

As the development of the semiconductor chip is booming, various electronic products are provided one after another. The chip package structure with multiple electrical processing functions plays an important role in electronic products.

A conventional chip package structure includes a substrate, a die, a bonding wire and a sealant. The substrate has a substrate pad. The die has a die pad. One end of the bonding wire is soldered on the substrate pad, and the other end of the bonding wire is soldered on the substrate pad. Thus, the die is electrically connected to the substrate through the bonding wire for transmitting various electrical signals.

As the electrical signals of the die are transmitted through the substrate pad and the die pad, the quality of the substrate pad and the die pad is very critical to transmission quality. Normally, one chip package structure includes tens (or even hundreds) of substrate pads and die pads, and one poor substrate pad or die pad alone would suffice to severely deteriorate the electrical properties of the chip package structure. Thus, the semiconductor industry has always been engaged in the improvement in the quality of the pad.

### SUMMARY OF THE INVENTION

The invention is directed to a semiconductor package structure. Materials of different functions are stacked on the metal base, so that the structural strength of the pad is reinforced and the electrical characteristics of the pad are improved.

According to a first aspect of the present invention, a semiconductor package structure is provided. The semiconductor package structure includes a first semiconductor element, a second semiconductor element, a bonding wire and a molding compound. The first semiconductor element includes a semiconductor die and a pad. The pad is disposed above the semiconductor die and includes a metal base, a hard metal layer and an anti-oxidant metal layer. The hard metal layer is disposed above the metal base. The hardness of the hard metal layer is larger than that of the metal base. The anti-oxidant metal layer is disposed above the hard metal layer. The activity of the anti-oxidant metal layer is lower than that of the hard metal layer. The first semiconductor element is disposed above the second semiconductor element. The bonding wire connects the pad of the first semiconductor element with the second semiconductor element. The molding compound seals the first semiconductor element and the bonding wire and covers the second semiconductor element.

The invention will become apparent from the following detailed description of the preferred but non-limiting embodiments. The following description is made with reference to the accompanying drawings.

### BRIEF DESCRIPTION OF THE DRAWINGS

FIG. 1 shows a semiconductor package structure according to a first embodiment of the invention;

FIG. 2 shows a semiconductor package structure according to a second embodiment of the invention;

FIG. 3 shows a semiconductor package structure according to a third embodiment of the invention; and

FIG. 4 shows a semiconductor package structure according to a fourth embodiment of the invention.

### DETAILED DESCRIPTION OF THE INVENTION

Preferred embodiments are disclosed below for elaborating the invention. However, the following embodiments are for the purpose of elaboration only, not for limiting the scope of protection of the invention. Besides, secondary elements are omitted in the drawing of the following embodiments to highlight the technical features of the invention.

### First Embodiment

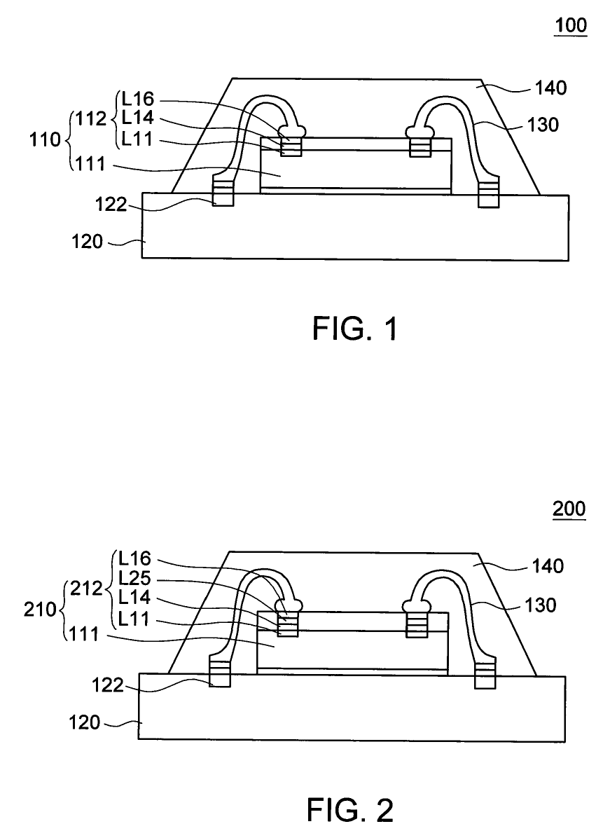

Referring to FIG. 1, a semiconductor package structure 100 according to a first embodiment of the invention is shown. The semiconductor package structure 100 includes a first semiconductor element 110, a second semiconductor element 120, a bonding wire 130, and a molding compound 140. The bonding wire is exemplified by a gold wire or a copper wire. The first semiconductor element 110 includes a semiconductor die 111 and a pad 112. The second semiconductor element 120 is exemplified by a substrate, a wafer or a lead frame. In the present embodiment of the invention, the second semiconductor element 120 is exemplified by a substrate. The first semiconductor element 110 is disposed above the second semiconductor element 120. The second semiconductor element 120 includes at least one pad 122. One end of the bonding wire 130 is soldered on the pad 112 of the first semiconductor element 110, and the other end of the bonding wire 130 is soldered on the pad 122 of the second semiconductor element 120. The first semiconductor element 110 transmits electrical signals to the second semiconductor element 120 through the connection of the bonding wire 130. The molding compound 140 seals the first semiconductor element 110 and the bonding wire 130 and covers the second semiconductor element 120. The PH value of the molding compound 140 ranges between 4 and 7.

In the present embodiment of the invention, the pad 112 includes a metal base L11, a hard metal layer L14 and an anti-oxidant metal layer L16. The metal base L11 is made from copper (Cu) or aluminum (Al).

The hard metal layer L14 is disposed above the metal base L11. The hardness of the hard metal layer L14 is larger than that of the metal base L11. Preferably, the hardness of the hard metal layer L14 is larger than that of the bonding wire 130. During the process of soldering the bonding wire 130, the welding gripper grips the bonding wire 130 to strike the pad 112, and the hard metal layer L14 having higher hardness avoids the pad 112 being damaged when stricken by the welding gripper. Based on the differences in the physical characteristics, the chemical characteristics and the formation method of the materials of different layers, the hard metal layer L14 can be made from cobalt (Co), iron (Fe), chromium (Cr), titanium (Ti), tantalum (Ta), titanium-tungsten (TiW) alloy, titanium-nitride (TiN) alloy or nickel (Ni). Cobalt (Co), iron (Fe) and nickel (Ni) are formed by way of electroless plating such as chemical plating. Chromium (Cr), titanium (Ti), tantalum (Ta), titanium-tungsten (TiW) alloy and titanium-nitride (TiN) alloy are formed by way of sputtering.

The anti-oxidant metal layer L16 is disposed above the hard metal layer L14. The activity of the anti-oxidant metal layer L16 is lower than that of the hard metal layer L14. The hard metal layer L14 and the metal base L11, having higher material activity, are easily oxidized when exposed in the air. Thus, by covering the hard metal layer L14 with the anti-oxidant metal layer L16 whose activity is lower, the hard metal layer L14 and the metal base L11 are prevented from being oxidized easily. Based on the differences in the physical characteristics, the chemical characteristics and the formation method of the materials of different layers, the anti-oxidant metal layer L16 can be made from palladium (Pd), gold (Au), silver (Ag) or platinum (Pt) for example.

The metal base L11, the hard metal layer L14 and the anti-oxidant metal layer L16 are made from different materials. In order to obtain better quality, the material combination of the hard metal layer L14 and the anti-oxidant metal layer L16 which are disposed on top of the metal base L11 has to take many factors such as the physical characteristics, the chemical characteristics and the formation method of the materials into account. For example, factors such as the differences in the coefficients of thermal expansion of different materials, the possibilities of chemical reactions between different materials and the differences in the electron transport characteristics of different materials all affect the structural strength and electrical characteristics of the pad 112. A number of preferred material combinations of the hard metal layer L14 and the anti-oxidant metal layer L16 obtained from experiments are exemplified in Table 1.

TABLE 1

| | | Anti-Oxidant Metal Layer |
|---|---|---|
| | Hard Metal Layer L14 | L16 |
| Thickness | 0.45-20 um | 0.005-2 um |
| Material | cobalt (Co) | Palladium (Pd) |
| | cobalt (Co) | gold (Au) |
| | cobalt (Co) | silver (Ag) |
| | cobalt (Co) | platinum (Pt) |
| | iron (Fe) | palladium (Pd) |
| | iron (Fe) | gold (Au) |
| | iron (Fe) | silver (Ag) |
| | iron (Fe) | platinum (Pt) |
| | chromium (Cr) | palladium (Pd) |
| | chromium (Cr) | gold (Au) |
| | chromium (Cr) | silver (Ag) |
| | chromium (Cr) | platinum (Pt) |
| | titanium (Ti) | palladium (Pd) |
| | titanium (Ti) | gold (Au) |
| | titanium (Ti) | silver (Ag) |
| | titanium (Ti) | platinum (Pt) |
| | tantalum (Ta) | palladium (Pd) |
| | tantalum (Ta) | gold (Au) |
| | tantalum (Ta) | silver (Ag) |
| | tantalum (Ta) | platinum (Pt) |
| | titanium-tungsten (TiW) | palladium (Pd) |
| | alloy | |
| | titanium-tungsten (TiW) | gold (Au) |
| | alloy | |
| | titanium-tungsten (TiW) | silver (Ag) |
| | alloy | |
| | titanium-tungsten (TiW) | platinum (Pt) |
| | alloy | |
| | titanium-nitride (TiN) alloy | palladium (Pd) |
| | titanium-nitride (TiN) alloy | gold (Au) |
| | titanium-nitride (TiN) alloy | silver (Ag) |
| | titanium-nitride (TiN) alloy | platinum (Pt) |

Besides, the thickness of the hard metal layer L14 and the anti-oxidant metal layer L16 is an important factor that affects the structural strength of the pad 112. For example, if the hard metal layer L14 is too thin, the collision shielding effect might be deteriorated. If the hard metal layer L14 is too thick, the electron transport rate of the pad 112 might be affected. If the anti-oxidant metal layer L16 is too thin, the anti-oxidation effect might be affected. If the anti-oxidant metal layer L16 is too thick, the problem of stress mismatching might occur. It is concluded from several experiments that better results can be obtained when the thickness of the hard metal layer L14 ranges between 0.45 and 20 micrometers (μm) and when the thickness of the anti-oxidant metal layer L16 ranges between 0.005 and 2 μm.

### Second Embodiment

Referring to FIG. 2, a semiconductor package structure 200 according to a second embodiment of the invention is shown. The semiconductor package structure 200 of the present embodiment of the invention differs with the semiconductor package structure 100 of the first embodiment in that the pad 212 of the first semiconductor element 210 of the present embodiment of the invention further includes an anti-oxidant metal layer L25, and other similarities are not repeated here.

As indicated in FIG. 2, the anti-oxidant metal layer L25 is disposed between the hard metal layer L14 and the anti-oxidant metal layer L16. The activity of the anti-oxidant metal layer L25 is also lower than that of the hard metal layer L14. In the present embodiment of the invention, the anti-oxidant metal layer L25 is interposed between the hard metal layer L14 and the anti-oxidant metal layer L16, not only increasing the anti-oxidation effect, but also increasing the bonding effect between the hard metal layer L14 and the anti-oxidant metal layer L16. Based on the differences in the physical characteristics, the chemical characteristics and the formation method of the materials of different layers, the anti-oxidant metal layer L25 can be made from palladium (Pd), chromium-copper alloy (CrCu) or nickel-vanadium alloy (NiV).

The metal base L11, the hard metal layer L14, the anti-oxidant metal layer L25 and the anti-oxidant metal layer L16 are made from different materials. In order to achieve a preferred quality level, the material combination of the anti-oxidant metal layer L25 and the anti-oxidant metal layer L16 which are disposed on top of the hard metal layer L14 of the metal base L11 has to take many factors such as the physical characteristics, the chemical characteristics and the formation method of the materials into account. A number of preferred material combinations of the hard metal layer L14, the anti-oxidant metal layer L25 and the anti-oxidant metal layer L16 obtained from experiments are exemplified in Table 2.

TABLE 2

| | | Anti-Oxidant | Anti-Oxidant |
|---|---|---|---|
| | Hard Metal | Metal Layer | Metal |
| | Layer L14 | L25 | Layer L16 |
| Thickness | 0.45-20 um | 0.01-3 um | 0.005-2 um |
| Material | cobalt (Co) | platinum (Pt) | gold (Au) |
| | cobalt (Co) | platinum (Pt) | silver (Ag) |
| | iron (Fe) | platinum (Pt) | gold (Au) |
| | iron (Fe) | platinum (Pt) | silver (Ag) |
| | chromium (Cr) | platinum (Pt) | gold (Au) |
| | chromium (Cr) | platinum (Pt) | silver (Ag) |
| | titanium (Ti) | platinum (Pt) | gold (Au) |
| | titanium (Ti) | platinum (Pt) | silver (Ag) |
| | tantalum (Ta) | platinum (Pt) | gold (Au) |
| | tantalum (Ta) | platinum (Pt) | silver (Ag) |
| | titanium-tungsten | platinum (Pt) | gold (Au) |
| | (TiW) alloy | | |
| | titanium-tungsten | platinum (Pt) | silver (Ag) |
| | (TiW) alloy | | |
| | titanium-nitride | platinum (Pt) | gold (Au) |
| | (TiN) alloy | | |
| | titanium-nitride | platinum (Pt) | silver (Ag) |
| | (TiN) alloy | | |
| | chromium (Cr) | chromium-copper alloy | gold (Au) |
| | | (CrCu) | |
| | chromium (Cr) | chromium-copper alloy | silver (Ag) |
| | | (CrCu) | |
| | chromium (Cr) | chromium-copper alloy | platinum |
| | | (CrCu) | (Pt) |
| | chromium (Cr) | chromium-copper alloy | palladium |
| | | (CrCu) | (Pd) |
| | titanium (Ti) | nickel-vanadium alloy | gold (Au) |
| | | (NiV) | |
| | titanium (Ti) | nickel-vanadium alloy | palladium |
| | | (NiV) | (Pd) |
| | titanium (Ti) | nickel-vanadium alloy | silver (Ag) |
| | | (NiV) | |
| | titanium (Ti) | nickel-vanadium alloy | platinum |
| | | (NiV) | (Pt) |
| | titanium-tungsten | nickel-vanadium alloy | gold (Au) |
| | (TiW) alloy | (NiV) | |
| | titanium-tungsten | nickel-vanadium alloy | palladium |
| | (TiW) alloy | (NiV) | (Pd) |
| | titanium-tungsten | nickel-vanadium alloy | silver (Ag) |
| | (TiW) alloy | (NiV) | |
| | titanium-tungsten | nickel-vanadium alloy | platinum |
| | (TiW) alloy | (NiV) | (Pt) |
| | titanium-nitride | nickel-vanadium alloy | gold (Au) |
| | (TiN) alloy | (NiV) | |
| | titanium-nitride | nickel-vanadium alloy | palladium |
| | (TiN) alloy | (NiV) | (Pd) |
| | titanium-nitride | nickel-vanadium alloy | silver (Ag) |
| | (TiN) alloy | (NiV) | |
| | titanium-nitride | nickel-vanadium alloy | platinum |
| | (TiN) alloy | (NiV) | (Pt) |
| | tantalum (Ta) | nickel-vanadium alloy | gold (Au) |
| | | (NiV) | |
| | tantalum (Ta) | nickel-vanadium alloy | palladium |
| | | (NiV) | (Pd) |
| | tantalum (Ta) | nickel-vanadium alloy | silver (Ag) |
| | | (NiV) | |
| | tantalum (Ta) | nickel-vanadium alloy | platinum |
| | | (NiV) | (Pt) |

Besides, the thickness of the anti-oxidant metal layer L25 is an important factor that affects the structural strength of the pad 212. For example, if the anti-oxidant metal layer L25 is too thin, the anti-oxidation effect and the bonding effect between the hard metal layer L14 and the anti-oxidant metal layer L16 might be affected. If the anti-oxidant metal layer L25 is too thick, the problem of stress mismatching might occur. It is concluded from several experiments that better results can be obtained when the thickness of the anti-oxidant metal layer L25 ranges between 0.001 and 3 μm.

### Third Embodiment

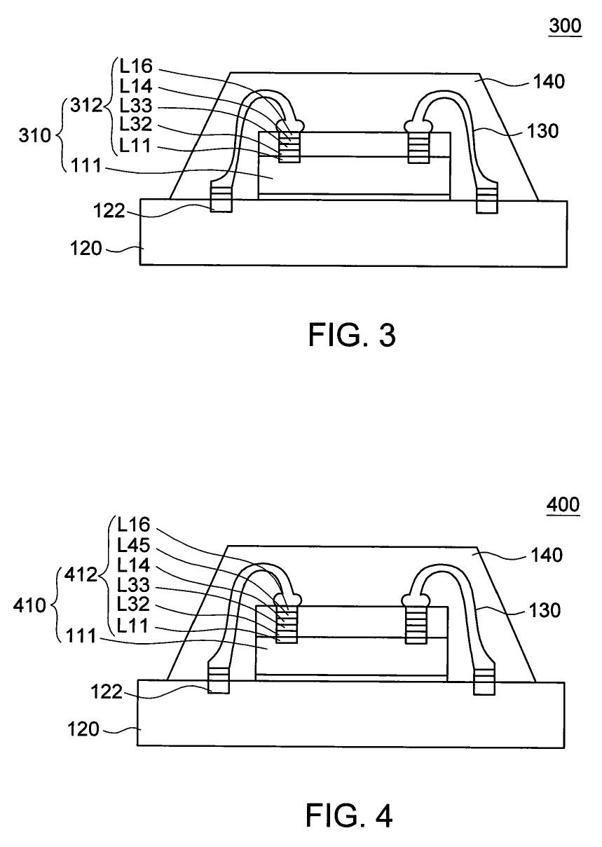

Referring to FIG. 3, a semiconductor package structure 300 according to a third embodiment of the invention is shown. The semiconductor package structure 300 of the present embodiment of the invention differs with the semiconductor package structure 100 of the first embodiment in that the pad 312 of the first semiconductor element 310 of the present embodiment of the invention further includes a seed layer L32 and a conductive layer L33, and other similarities are not repeated here.

As indicated in FIG. 3, the seed layer L32 is disposed above the metal base L11, the conductive layer L33 is disposed between the seed layer L32 and the hard metal layer L14. In the present embodiment of the invention, the seed layer L32 and the conductive layer L33 are interposed between the metal base L11 and the hard metal layer L14, not only making it easier for the hard metal layer L14 to be formed by way of electroplating, but also increasing the bonding effect between the hard metal layer L14 and the metal base L11. Based on the differences in the physical characteristics, the chemical characteristics and the formation method of the materials of different layers, the seed layer L32 can be made from titanium (Ti) titanium, titanium-tungsten (TiW) alloy, titanium-nitride (TiN) alloy or tantalum (Ta), the conductive layer L33 can be made from gold (Au) for example.

The metal base L11, the seed layer L32, the conductive layer L33, the hard metal layer L14, the anti-oxidant metal layer L16 are made from different materials. In order to achieve a preferred quality level, the conductive layer L33, the material combination of the hard metal layer L14 and the anti-oxidant metal layer L16 which are disposed on top of the seed layer L32 of the metal base L11 has to take many factors such as the physical characteristics, the chemical characteristics and the formation method of the materials into account. A number of preferred material combinations of the seed layer L32, the conductive layer L33, the hard metal layer L14 and the anti-oxidant metal layer L16 obtained from experiments are exemplified in Table 3.

TABLE 3

| | | | | Anti-Oxidant |
|---|---|---|---|---|
| | | Conductive | Hard Metal | Metal Layer |
| | Seed Layer L32 | Layer L33 | Layer L14 | L16 |
| Thickness | 0.1-1 um | 0.1-1 um | 0.45-20 um | 0.005-2 um |
| Material | titanium (Ti) | gold (Au) | nickel (Ni) | gold (Au) |
| | titanium (Ti) | gold (Au) | nickel (Ni) | palladium |
| | | | | (Pd) |
| | titanium (Ti) | gold (Au) | iron (Fe) | gold (Au) |
| | titanium (Ti) | gold (Au) | iron (Fe) | palladium |
| | | | | (Pd) |
| | titanium-tungsten | gold (Au) | nickel (Ni) | gold (Au) |
| | (TiW) alloy | | | |
| | titanium-tungsten | gold (Au) | nickel (Ni) | palladium |
| | (TiW) alloy | | | (Pd) |
| | titanium-tungsten | gold (Au) | iron (Fe) | gold (Au) |
| | (TiW) alloy | | | |
| | titanium-tungsten | gold (Au) | iron (Fe) | palladium |
| | (TiW) alloy | | | (Pd) |
| | titanium-nitride | gold (Au) | nickel (Ni) | gold (Au) |
| | titanium-nitride | gold (Au) | nickel (Ni) | palladium |
| | (TiN) alloy | | | (Pd) |
| | titanium-nitride | gold (Au) | iron (Fe) | gold (Au) |
| | (TiN) alloy | | | |
| | titanium-nitride | gold (Au) | iron (Fe) | palladium |
| | (TiN) alloy | | | (Pd) |
| | tantalum (Ta) | gold (Au) | nickel (Ni) | gold (Au) |
| | tantalum (Ta) | gold (Au) | nickel (Ni) | palladium |
| | | | | (Pd) |
| | tantalum (Ta) | gold (Au) | iron (Fe) | gold (Au) |
| | tantalum (Ta) | gold (Au) | iron (Fe) | palladium |
| | | | | (Pd) |

Besides, the thickness of the seed layer L32 and the conductive layer L33 is an important factor that affects the structural strength of the pad 312. For example, if the seed layer L32 and the conductive layer L33 are too thin, the formation of the hard metal layer L14 by way of electroless plating might be affected. If the seed layer L32 is too thick, more manufacturing hours will be required. It is concluded from several experiments that better results can be obtained when the thickness of the seed layer L32 ranges between 0.1 and 1 μm and the thickness of the conductive layer L33 ranges between 0.1 and 1 μm.

### Fourth Embodiment

Referring to FIG. 4, a semiconductor package structure according to a fourth embodiment of the invention is shown. The semiconductor package structure 400 of the present embodiment of the invention differs with the semiconductor package structure 300 of the third embodiment in that the pad 412 of the first semiconductor element 410 of the present embodiment of the invention further includes an anti-oxidant metal layer L45, and other similarities are not repeated here.

As indicated in FIG. 4, the anti-oxidant metal layer L45 is disposed between the hard metal layer L14 and the anti-oxidant metal layer L16. The activity of the anti-oxidant metal layer L45 is lower than that of the hard metal layer L14. In the present embodiment of the invention, the anti-oxidant metal layer L45 is interposed between the hard metal layer L14 between the anti-oxidant metal layer L16, not only increasing the anti-oxidation effect, but also increasing the bonding effect between the hard metal layer L14 and the anti-oxidant metal layer L16. Based on the differences in the physical characteristics, the chemical characteristics and the formation method of the materials of different layers, the anti-oxidant metal layer L45 can be made from palladium (Pd), chromium-copper alloy (CrCu) or nickel-vanadium alloy (NiV) for example.

The metal base L11, the seed layer L32, the conductive layer L33, the hard metal layer L14, the anti-oxidant metal layer L45 and the anti-oxidant metal layer L16 are made from different materials. In order to achieve a preferred quality level, the material combination of the conductive layer L33, the hard metal layer L14, the anti-oxidant metal layer L45 and the anti-oxidant metal layer L16 which are disposed on top of the seed layer L32 of the metal base L11 has to take many factors such as the physical characteristics, the chemical characteristics and the formation method of the materials into account. A number of preferred material combinations of the seed layer L32, the conductive layer L33, the hard metal layer L14, the anti-oxidant metal layer L45 and the anti-oxidant metal layer L16 obtained from experiments are exemplified in Table 4.

TABLE 4

| | | Conductive | | Anti-Oxidant | Anti-Oxidant |
|---|---|---|---|---|---|
| | | Layer | Hard Metal | Metal Layer | Metal Layer |
| | Seed Layer L32 | L33 | Layer L14 | L45 | L16 |
| Thickness | 0.1-1 um | 0.1-1 | 0.45-20 | 0.01-3 um | 0.005-2 um |
| | | um | um | | |
| Material | titanium (Ti) | gold (Au) | nickel (Ni) | palladium | gold (Au) |
| | | | | (Pd) | |
| | titanium (Ti) | gold (Au) | iron (Fe) | palladium | gold (Au) |
| | | | | (Pd) | |
| | titanium-tungsten | gold (Au) | iron (Fe) | palladium | gold (Au) |
| | (TiW) alloy | | | (Pd) | |
| | titanium nickel | gold (Au) | iron (Fe) | palladium | gold (Au) |
| | (TiN) alloy | | | (Pd) | |
| | tantalum (Ta) | gold (Au) | iron (Fe) | palladium | gold (Au) |
| | | | | (Pd) | |

According to the semiconductor package structure and the pad using the same disclosed in the above embodiments of the invention, materials of different functions are stacked on the metal base, so that the structural strength of the pad is reinforced and the electrical characteristics of the pad are improved. Preferably, with the design of the combinations of materials and thickness, the structural strength and electrical characteristics of the pad can further be improved.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A semiconductor package structure, comprising:
a first semiconductor element, comprising:
a semiconductor die; and
a pad disposed above the semiconductor die, comprising:
a metal base;
a hard metal layer disposed above the metal base, wherein the hardness of the hard metal layer is larger than that of the metal base; and
a first anti-oxidant metal layer disposed above the hard metal layer, wherein the activity of the first anti-oxidant metal layer is lower than that of the hard metal layer;
a second semiconductor element, wherein the first semiconductor element is disposed above the second semiconductor element; and
a bonding wire connected to the pad of the first semiconductor element and the second semiconductor element.
a molding compound sealing the first semiconductor element and the bonding wire and covering the second semiconductor element.

2. The semiconductor package structure according to claim 1, wherein the second semiconductor element is a substrate, a wafer or a lead frame.

3. The semiconductor package structure according to claim 1, wherein the hardness of the hard metal layer is larger than that of the bonding wire.

4. The semiconductor package structure according to claim 1, wherein the metal base, the hard metal layer and the first anti-oxidant metal layer are made from different materials.

5. The semiconductor package structure according to claim 1, wherein the PH value of the molding compound ranges between 4 and 7.

6. The semiconductor package structure according to claim 1, wherein the hard metal layer is made from cobalt (Co), iron (Fe), chromium (Cr), titanium (Ti), tantalum (Ta), titanium-tungsten (TiW) alloy, titanium-nitride (TiN) alloy or nickel (Ni).

7. The semiconductor package structure according to claim 1, wherein the hard metal layer is made from cobalt (Co) or iron (Fe), and the hard metal layer is formed by way of electroless plating.

8. The semiconductor package structure according to claim 7, wherein the hard metal layer is formed by way of chemical plating.

9. The semiconductor package structure according to claim 7, wherein the hard metal layer is made from chromium (Cr), titanium (Ti), tantalum (Ta), titanium-tungsten (TiW) alloy, titanium-nitride (TiN) alloy or nickel (Ni), and the hard metal layer is formed by way of sputtering.

10. The semiconductor package structure according to claim 1, wherein the thickness of the hard metal layer ranges between 0.45 and 20 μm.

11. The semiconductor package structure according to claim 1, wherein the first anti-oxidant metal layer is made from palladium (Pd), gold (Au), silver (Ag) or platinum (Pt).

12. The semiconductor package structure according to claim 1, wherein the thickness of the first anti-oxidant metal layer ranges between 0.005 and 2 μm.

13. The semiconductor package structure according to claim 1, further comprising:
a second anti-oxidant metal layer disposed between the hard metal layer and the first anti-oxidant metal layer, wherein the activity of the second anti-oxidant metal layer is lower than that of the hard metal layer.

14. The semiconductor package structure according to claim 13, wherein the metal base, the hard metal layer, the second anti-oxidant metal layer and the first anti-oxidant metal layer are made from different materials.

15. The semiconductor package structure according to claim 13, wherein the second anti-oxidant metal layer is made from palladium (Pd), chromium-copper alloy (CrCu) or nickel-vanadium alloy (NiV).

16. The semiconductor package structure according to claim 13, wherein the thickness of the second anti-oxidant metal layer ranges between 0.01 and 3 μm.

17. The semiconductor package structure according to claim 13, wherein the pad further comprises:
a seed layer disposed above the metal base; and
a conductive layer disposed between the seed layer and the hard metal layer.

18. The semiconductor package structure according to claim 17, wherein the metal base, the seed layer, the conductive layer, the hard metal layer and the first anti-oxidant metal layer are made from different materials.

19. The semiconductor package structure according to claim 17, wherein the seed layer is made from titanium (Ti) titanium, titanium-tungsten (TiW) alloy, titanium-nitride (TiN) alloy or tantalum (Ta).

20. The semiconductor package structure according to claim 17, wherein the thickness of the seed layer ranges between 0.1 and 1 μm.

21. The semiconductor package structure according to claim 17, wherein the conductive layer is made from gold (Au).

22. The semiconductor package structure according to claim 17, wherein the thickness of the conductive layer ranges between 0.1 and 1 μm.

23. The semiconductor package structure according to claim 17, wherein the pad further comprises:
a second anti-oxidant metal layer disposed between the hard metal layer and the first anti-oxidant metal layer, wherein the activity of the second anti-oxidant metal layer is lower than that of the hard metal layer.

24. The semiconductor package structure according to claim 23, wherein the metal base, the seed layer, the conductive layer, the hard metal layer, the second anti-oxidant metal layer and the first anti-oxidant metal layer are made from different materials.

25. The semiconductor package structure according to claim 1, wherein the bonding wire is a gold wire or a copper wire.
